(19) United States
(12) Patent Application Publication
(10) Pub. No.: US 2024/0047279 A1
(43) Pub. Date: Feb. 8, 2024

(54) USING SEQUENCE MINING TO PREDICT QUALITY AND YIELD

(71) Applicant: International Business Machines Corporation, Armonk, NY (US)

(72) Inventors: Robert Jeffrey Baseman, Brewster, NY (US); Elham Khabiri, Briarcliff Manor, NY (US); Anuradha Bhamidipaty, Yorktown Heights, NY (US); Yingjie Li, Chappaqua, NY (US); Srideepika Jayaraman, White Plains, NY (US); Bhavna Agrawal, Armonk, NY (US); Jeffrey Owen Kephart, Cortlandt Manor, NY (US)

(21) Appl. No.: 17/817,688

(22) Filed: Aug. 5, 2022

(51) Int. Cl. H01L 21/66; G06K 9/62; H01L 21/67

(52) U.S. Cl. CPC H01L 22/20; G06K 9/6232; H01L 21/67253; H01L 22/10

(57) ABSTRACT

Embodiments of the invention are directed to a computer-implemented method. A non-limiting example of the computer-implemented method includes accessing, using a processor system, a process-step sequence that includes a plurality process-steps and a plurality of queue-times. A process-step sequence mining operation is applied to the process-step sequence, wherein the process-step sequence mining operation is operable to make a prediction of an impact of a portion of the process-step sequence on a characteristic of a product generated by the process-step sequence.

### BACKGROUND

The present invention relates in general to programmable computers. More specifically, the present invention relates to computing systems, computer-implemented methods, and computer program products operable to use novel process-step sequence mining techniques to predict the semiconductor product quality and wafer/die yield that will result from a process-step sequence. In accordance with aspects of the invention, the novel process-step sequence mining is based at least in part on a sequence-based analysis of an entire process-step sequence.

The term “queue-time” refers to the time a wafer-under-fabrication waits between adjacent individual fabrication operations or process steps. The individual process steps can represent as many as 1,000 separate queue-times. Semiconductor wafers are fabricated in a series of stages, including a front-end-of-line (FEOL) stage, a middle-of-line (MOL) stage and a back-end-of-line (BEOL) stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The FEOL stage processes also involve the formation of a plurality of IC chips or semiconductor die on the surface of a semiconductor wafer. Each IC chip contains circuits formed by electrically connecting active and passive components. The MOL stage forms interconnect structures (e.g., lines, wires, metal-filled vias, contacts, and the like) that communicatively couple to active regions (e.g., gate, source, and drain) of the device element. During the BEOL stage, layers of interconnect structures are formed above these logical and functional layers to complete the semiconductor wafer. The FEOL, MOL, and BEOL fabrication stages require the integration of as many as 1000 individual process-steps such as thin film deposition and modification processes.

### SUMMARY

Embodiments of the invention are directed to a computer-implemented method. A non-limiting example of the computer-implemented method includes accessing, using a processor system, a process-step sequence that includes a plurality process-steps and a plurality of queue-times. A process-step sequence mining operation is applied to the process-step sequence, wherein the process-step sequence mining operation is operable to make a prediction of an impact of a portion of the process-step sequence on a characteristic of a product generated by the process-step sequence.

Embodiments of the invention are also directed to computer systems and computer program products having substantially the same features, technical effects, and technical benefits as the computer-implemented method described above.

Additional features and advantages are realized through techniques described herein. Other embodiments and aspects are described in detail herein. For a better understanding, refer to the description and to the drawings.

### BRIEF DESCRIPTION OF THE DRAWINGS

The subject matter which is regarded as embodiments is particularly pointed out and distinctly claimed in the claims at the conclusion of the specification. The foregoing and other features and advantages of the embodiments are apparent from the following detailed description taken in conjunction with the accompanying drawings in which:

FIG. 1 depicts a block diagram illustrating a process-step sequence (PSS) that has been analyzed using novel PSS mining operations in accordance with embodiments of the invention;

FIG. 2 depicts a PSS mining system being trained to perform PSS mining operations in accordance with embodiments of the invention;

FIG. 3 depicts a flow diagram illustrating a computer-implemented method of training a PSS mining system in accordance with embodiments of the invention;

FIG. 4 depicts a trained PSS mining system in accordance with embodiments of the invention;

FIG. 5 depicts a flow diagram illustrating a computer-implemented method of operating a trained PSS mining system in accordance with embodiments of the invention;

FIG. 6 depicts tables and diagrams illustrating a non-limiting example of an encoding operation in accordance with embodiments of the invention;

FIG. 7 depicts diagrams illustrating a non-limiting example of a dimensionality reduction operation in accordance with embodiments of the invention;

FIG. 8 depicts a diagram illustrating a non-limiting example of a dimensionality reduction operation operable to utilize word embeddings in accordance with embodiments of the invention;

FIG. 9 depicts a table and a diagram illustrating a non-limiting example of a clustering operation in accordance with embodiments of the invention;

FIG. 10A depicts a diagram illustrating a non-limiting example of cluster evaluation operations in accordance with embodiments of the invention;

FIG. 10B depicts a diagram illustrating a non-limiting example of cluster evaluation operations in accordance with embodiments of the invention;

FIG. 11A depicts tables further illustrating non-limiting examples of cluster evaluation operations in accordance with embodiments of the invention;

FIG. 11B depicts a table further illustrating non-limiting examples of cluster evaluation operations in accordance with embodiments of the invention;

FIG. 11C depicts a table further illustrating non-limiting examples of cluster evaluation operations in accordance with embodiments of the invention;

FIG. 11D depicts a table illustrating a non-limiting example of generating an overall cluster quality metric by weighting different cluster quality metrics from different sources in accordance with embodiments of the invention;

FIG. 12A depicts tables further illustrating non-limiting examples of cluster evaluation operations in accordance with embodiments of the invention;

FIG. 12B depicts a table further illustrating a non-limiting example of identifying and selecting a clustering technique in accordance with embodiments of the invention;

FIG. 13 depicts a table and a diagram illustrating non-limiting examples of pattern sequence extraction operations in accordance with embodiments of the invention;

FIG. 14 depicts a machine learning system that can be utilized to implement aspects of the invention;

FIG. 15 depicts a learning phase that can be implemented by the machine learning system shown in FIG. 14;

FIG. 16 depicts details of an exemplary computing system operable to implement embodiments of the invention; and

FIG. 17 depicts a semiconductor fabrication system operable to implement embodiments of the invention.

In the accompanying figures and following detailed description of the disclosed embodiments, the various elements illustrated in the figures are provided with three digit reference numbers. In some instances, the leftmost digits of each reference number corresponds to the figure in which its element is first illustrated.

### DETAILED DESCRIPTION

For the sake of brevity, conventional techniques related to making and using aspects of the invention may or may not be described in detail herein. In particular, various aspects of computing systems and specific computer programs to implement the various technical features described herein are well known. Additionally, conventional techniques related to semiconductor product and integrated circuit (IC) fabrication are also well known. Accordingly, in the interest of brevity, many conventional implementation details are only mentioned briefly herein or are omitted entirely without providing the well-known system and/or process details.

Turning now to an overview of technologies that are relevant to aspects of the invention, a semiconductor product includes, but is not limited to a semiconductor die/chip, a semiconductor wafer, and a semiconductor wafer lot. Establishing and maintaining high fabrication yields and reliable product quality are important in commercial semiconductor product fabrication systems, given the high capital costs thereof. Because of their extreme complexity, known semiconductor fabrication systems include a large number of defect generating mechanisms, which makes the discovery of factors that influence semiconductor product yield and quality difficult. For example, an entire semiconductor fabrication sequence involves an exceedingly large and difficult to analyze amount of data and combinatorial dependence structures (e.g., data dependency). Thus, methods developed to identify opportunities to improve yield and quality, or to diagnose yield and quality aberrations, are limited in the scale and scope of data considered to factors that are known historically to be influential.

Queue-time (QT) is the time a semiconductor product spends waiting between individual semiconductor fabrication processes. QTs can be influenced by a wide variety of factors including fabrication line loading, tool availabilities, and the engineering analysis time required to address unexpected intermediate measurements. QT can vary widely in a given semiconductor product fabrication process sequence, reflecting different line loading and tool availabilities. QTs between fabrication steps, or accumulated QTs between multiple fabrication steps, can influence a wide variety of semiconductor product characteristics, including but not limited to increasing or decreasing leakage current, increasing or decreasing threshold voltage, increasing or decreasing areas of the semiconductor products, increasing or decreasing operational frequencies of the semiconductor products, and the like. Additionally, significant product defects can be associated with the QTs between particular process steps in the process sequence. For example, after a deposition step, a semiconductor product can be exposed to air for only a limited amount of time before the quality of the deposited film will begin to degrade. BEOL metallization can suffer serious corrosion if a post-polish QT is not maintained below a critical threshold. Migration of RIE (Reactive Ion Etching) induced contamination from photoresist is observed if an etch-to-strip QT is not controlled.

Traditionally, efforts to discover the effects of QT on semiconductor product quality/yield have been limited to painstaking ad-hoc investigations, as well as optimizing individual QTs without effectively determining the impact of the individually optimized QT on quality/yield results of the entire process-step sequence.

Turning now to an overview of aspects of the invention, embodiments of the invention described herein provide computing systems, computer-implemented methods, and computer program products that use novel process-step sequence mining techniques to predict the semiconductor product quality/yield and/or wafer/die quality/yield of a process-step sequence. In accordance with some aspects of the invention, the novel process-step sequence mining operations are based at least in part on a sequence-based analysis of an entire process-step sequence (e.g., the entire fabrication process-step sequence that processes a raw wafer to output a testable wafer/die), thereby enabling the identification of rules that govern a QT's influence on quality and yield of the entire process-step sequence. In some aspects of the invention, the novel process-step sequence mining operations are operable to enable the identification of rules that govern the influence of a sequence of process-steps and their associated QT on quality and yield of an entire process-step sequence. By discovering the effects of QTs (and/or sequences of process-steps and their associated QTs) on product quality and yield of an entire process-step sequence, fabrication line controls can be generated that optimize product quality and yield for an entire process-step sequence.

In embodiments of the invention, the novel process-step sequence mining operations include encoding a process-step sequence, where the process-step sequence includes multiple individual process steps and associated QTs between the multiple individual process steps. Embodiments of the invention encode the entire process-step sequence (e.g., the entire fabrication process-step sequence that processes a raw wafer to output a testable wafer/die) in order to analyze the entire process-step sequence rather than separately analyzing the individual components (e.g., the individual process steps and the individual QTs) of the process-step sequence. Encoding the entire process-step sequence enables the novel process-step sequence mining operations to apply analysis techniques that reduce the burden of analyzing a large amount of data with combinatorial dependence structures (e.g., thousands of process-steps with as many as a million associated QTs), which enable the novel process-step sequence mining operations to explore and uncover the rules, conditions, and the like (e.g., quality-related rules/conditions and/or yield-related rules/conditions) that govern the entire process-step sequence. In aspects of the invention, the encoding operations transform the process-step sequence into symbols that are part of unique type of language domain referred to herein as a PSS (process-step sequence) language domain. In a natural language processing domain, sequences of symbols in the form of letters, words, and sentences are evaluated to derive their meaning in a given natural language domain such as the English language. For example, in the English language, the sequence of letters and words that read “I ran away and hid when I saw the tiger in the woods” has a different meaning from the sequence of letters and words that read “I stayed to confront the threat presented by the tiger when I saw the tiger in the woods.” In the novel PSS language domain, in accordance with aspects of the invention, the components of an entire PSS are converted to (or encoded into) symbols; and sequences of the encoded symbols are evaluated to understand how, for example, a given symbol (e.g., a QT) or a sequence of symbols (e.g., a sequence of process steps and their associated QTs) impact the quality or yield of semiconductor products produced by the entire process-step sequence.

In some embodiments of the invention, the analysis techniques perform a highly non-linear transformation of the encoded process-step sequence to a lower dimension space such that similarity metrics can be generated that identify the process-step sequences that are similar to one another. For example, process-step sequences that generate high yield and/or high semiconductor product quality can be identified, and the process-step sequence parameters (e.g., QTs, process-steps, QT sequences, process-step sequences, and QT/process-step sequences) that influence (or are essential to) the generation of high yield and/or high semiconductor product quality can be identified or extracted. Similarly, process-step sequences that generate low yield and/or low semiconductor product quality can be identified, and the process-step sequence parameters (e.g., QTs, process-steps, QT sequences, process-step sequences, and QT/process-step sequences) that influence (or are essential to) the generation of low yield and/or high semiconductor product quality can be identified or extracted. Other combinations of yield (high, medium, low) and semiconductor product quality levels (high, medium, low) can be generated. The process-step sequence parameters that influence or are essential to yield and/or semiconductor product quality are used to generate rules (or conditions, or machine learning models) that can be applied to new process-step sequences to determine the new process-step sequence's yield and/or semiconductor product quality performance. The process-step sequence parameters that influence or are essential to yield and/or semiconductor product quality for a given process-step sequence, along with the rules (or conditions, or machine learning models) that determine a process-step sequence's yield and/or semiconductor product quality performance can be applied to an optimization module/engine to optimize the tradeoffs between yield/quality and other potentially competing goals such as throughput.

In embodiments of the invention, the process-step sequence mining operations are implemented by a process-step sequence mining system, which can be trained using an encoder module, a dimensionality reduction module, and an untrained predictive module. Training data in the form of process-step sequences are provided to the untrained process-step sequence mining system for training the predictive model's task(s). In some embodiments of the invention, the predictive model's task is to predict the yield and the semiconductor product quality, in any combination, that result from a semiconductor fabrication process-step sequence. In general, yield is a quantitative measure of the quality of a semiconductor fabrication process-step sequence (or a fabrication line). Line yield refers to the number of good wafers produced without being scrapped (e.g., for critical defects such as chipping, metallization peels off, silicon dust contamination, cracks, and the like), and in general, measures the effectiveness of material handling, process control, and labor. Die yield refers to the number of good dice that pass wafer probe testing from wafers that reach that part of the process. Wafer probe testing is intended to prevent bad dice from being assembled into packages that are often extremely expensive and measures the effectiveness of process control, design margins, and particulate control. Thus, yield is a quantitative measurement of the process quality in terms of working wafers and/or working dies.

In some embodiments of the invention, the training process-step sequence data is annotated or labeled (i.e., the quality and yield characteristics of the training process-step sequences are known and provided). In some embodiments of the invention, the training process-step sequence data is not annotated or labeled (i.e., the quality and yield characteristics of the training process-step sequences are unknown). In some embodiments of the invention, the process-step sequence training data is a combination of annotated/labeled training data and non-annotated/non-labeled training data. The encoder module represents the components (i.e., the various process steps and their associated QTs) of the training process-step sequence as a sequence of symbols. Because the components of the training process-step sequence, taken collectively, have various relationships to the yield and semiconductor product quality produced by the training process-step sequence, the encoded components of the symbol sequence, taken collectively, also have various relationships to the yield and semiconductor product quality produced by the training process-step sequence. Additionally, because the training process-step sequence is now represented as symbols that have meaning (i.e., the previously-described various relationships to the yield and semiconductor product quality produced by the training process-step sequence), analysis techniques that draw meaning from symbol sequences (e.g., letters, words, sentences) can be leveraged to manage the large amount of data and combinatorial dependence structures (e.g., data dependency) in a given process-step sequence of a semiconductor fabrication system. Accordingly, the symbol sequence (or encoding sequence) that represents the components (i.e., the various process steps and their associated QTs) of the training process-step sequence can be applied to the dimensionality reduction module, and the dimensionality reduction module can use natural language processing (NLP) techniques (e.g., word embeddings) to reduce the dimensionality of the symbol sequence while preserving the meaning of the symbols sequence in the PSS language domain. This dimensionality reduction enables the process-step sequence to be analyzed in a manner that could not be accomplished through direct analysis of the non-encoded process-step sequence.

The to-be-trained predictive module receives the reduced dimensionality sequence symbols and applies various analysis techniques to uncover the rules that govern yield results and semiconductor product quality results achieved by the process-step sequence. In some embodiments of the invention, the predictive module uses machine learning algorithms (including NLP algorithms) to uncover the rules. The machine learning algorithms can learn in a supervised or unsupervised manner depending on whether the training process-step sequence is labeled or unlabeled. In some embodiments of the invention, the machine learning algorithms utilize clustering techniques to produce clusters that are correlated to yield and/or semiconductor product quality, and to further produce (or predict, or extract) the process-step sequence features (including QTs) that impact yield and/or semiconductor product quality. More specifically, the machine learning algorithms identify (or predict, or extract) respective distinctive features of the clusters with a large proportion of high-quality and low-quality semiconductor products, as well as the distinctive features of the clusters with a large proportion of high yield results and low yield results.

In some embodiments of the invention, the post-training predictive module is operable to infer from the distinctive features the process-step sequences (or portions of the process-step sequences) that are likely to produce high quality semiconductor products, low quality semiconductor products, high yields, and/or low yields. In embodiments of the invention, the semiconductor product produced by the process-step sequence includes a wafer having dies and completed integrated circuitry ready for testing. The trained predictive module incorporates the encoding operations and dimensionality reduction operations developed during training. In embodiments of the invention, the trained predictive module encodes a process-step sequence, reduces the dimensionality of the encoded process-step sequence, and maps process-step sequence to one or more clusters in order to identify cluster yield/quality distributions of the new process-step sequence. The trained predictive module uses the cluster yield/quality distributions (i.e., extracted yield/quality features) to predict the yield results and the semiconductor product quality results of the process-step sequence. In some embodiments of the invention, the process-step sequence mining system further includes or utilizes downstream modules to perform a variety of analyses and operations, including, for example generating controls that can be utilized to maintain selected QTs within limits that ensure high yield and/or high quality.

Accordingly, embodiments of the invention address and overcome the need to use painstaking ad-hoc investigation to discover the effects of QT and process-step sequence on semiconductor product yield and quality of an entire process-step sequence. By encoding the entire process-step sequence (including individual process steps and QTs) into symbols and sequences of symbols, embodiments of the invention enable the novel process-step sequence mining operations to apply analysis techniques (e.g., word embeddings and machine learning model training) that reduce the burden of analyzing a large amount of data with combinatorial dependence structures (e.g., thousands of process-steps with as many as a million QTs), which enables the novel process-step sequence mining operations to explore and uncover the rules, conditions, and the like (e.g., quality-related rules/conditions and/or yield-related rules/conditions) that govern the entire process-step sequence in a unique PSS language domain.

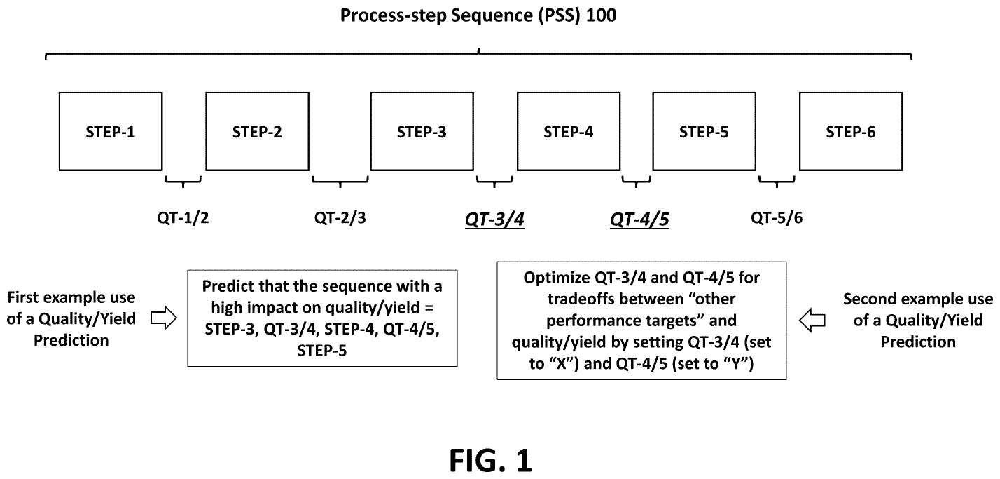

Turning now to a more detailed description of various embodiments of the invention, FIG. 1 depicts a simplified block diagram illustrating a process-step sequence (PSS) 100 having individual process-steps ((STEP-1, STEP-2, STEP-3, STEP-4, STEP-5, STEP-6) separated by associated QTs (QT-1/2, QT-2/3, QT-3/4, QT-4/5, QT-5/6). For ease of illustration and explanation, six process-steps and five QTs are depicted in FIG. 1. However, it is understood that any number of process-steps and QTs can be provided in the PSS 100. In embodiments of the invention where the PSS 100 is a semiconductor product fabrication process, the PSS 100 can include thousands of individual steps, including, for example, diffusion operations, lithography operations, etching operations, ion implantation, deposition and sputtering. Diffusion and ion implantation generally require longer processing time than other fabrication stages require less processing time. Some fabrication processes, e.g., those with long processing time, can be simultaneously performed on several wafer lots (commonly referred to as a “batch”). The cycle time of PSS 100 is the total time required by PSS 100 to produce a lot or wafer, from entering the PSS 100 to leaving the PSS 100. Cycle time includes time spent processing, as well as transport time and time spent waiting in queue (i.e., QT-1/2, QT-2/3, QT-3/4, QT-4/5, QT-5/6). The time spent waiting in queue can include time spent waiting for tools and time spent waiting for operators. In embodiments of the invention, PSS 100 is operable to produce a semiconductor product, which can be, for example, a testable wafer and/or a wafer having dies and completed integrated circuitry ready for testing.

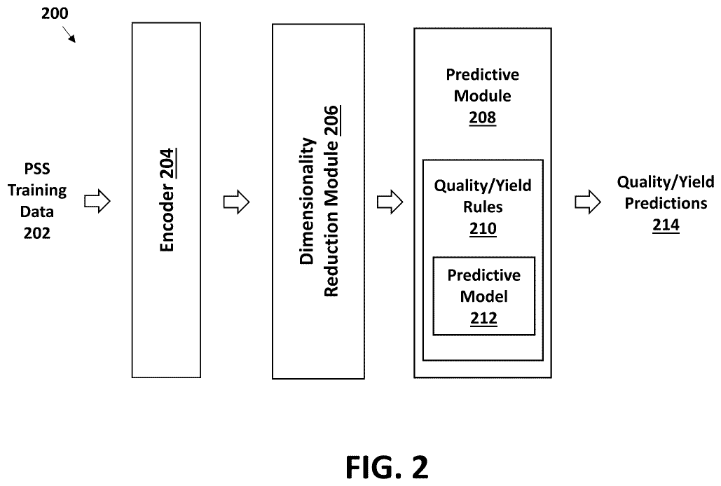

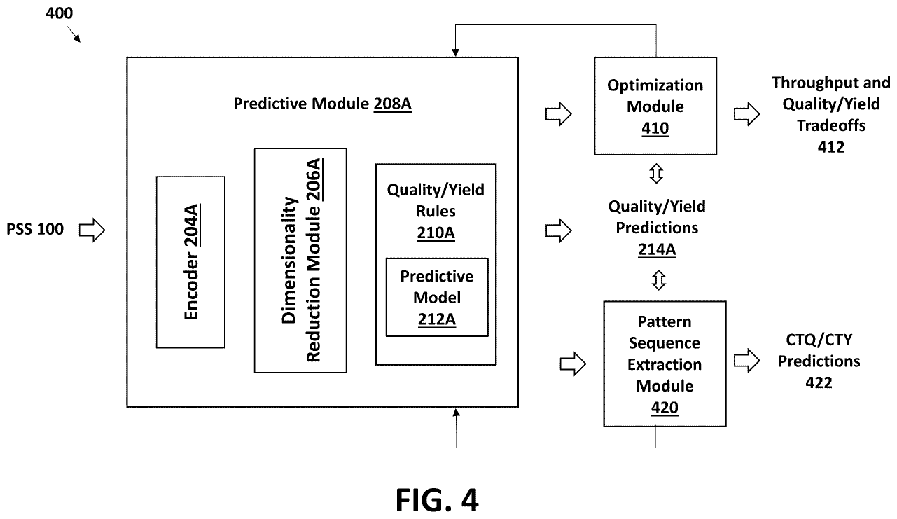

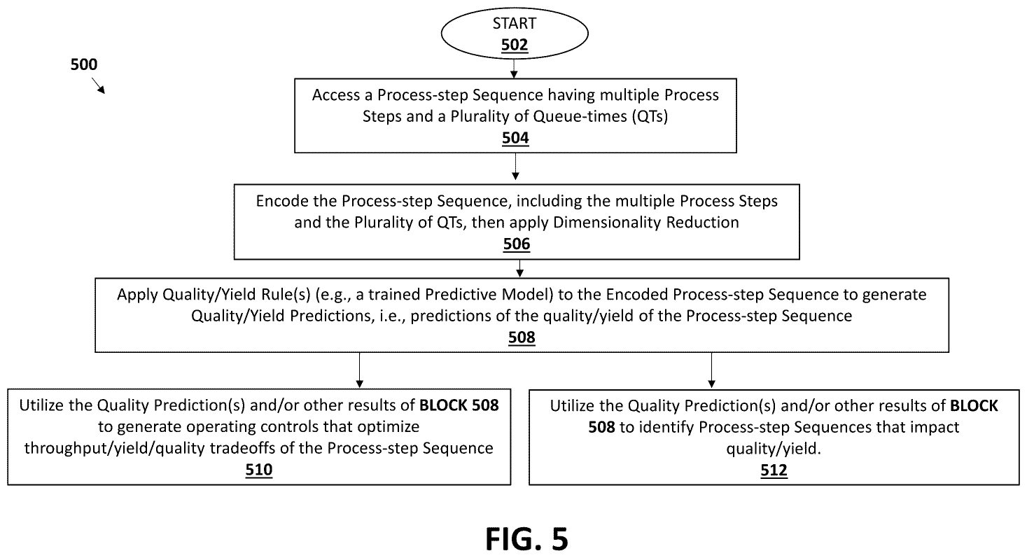

In embodiments of the invention, the PSS 100 has been analyzed using a novel PSS mining operation (e.g., the methodology 500 shown in FIG. 5) and a novel PSS mining system (e.g., the PSS mining system 400 shown in FIG. 4) operable to make quality/yield predictions (e.g., quality/yield predictions 214A shown in FIG. 4) about the quality/yield of semiconductor products that would be produced by the PSS 100. FIG. 1 depicts a first example use of a quality/yield prediction in which, for example, a pattern sequence extraction module (e.g., pattern sequence extraction module 420 shown in FIG. 4) has been used to identify (or predict) that the sequence with a high impact on quality/yield is STEP-3, QT-3/4, STEP-4, QT-4/5, STEP-5. FIG. 1 also depicts a second example use of a quality/yield prediction in which, for example, an optimization engine (e.g., optimization module 410 shown in FIG. 4) has been used to optimize QT-3/4 and QT-4/5 for tradeoffs between “other performance targets” and quality/yield by setting QT-3/4 (set to “X”) and QT-4/5 (set to “Y”). In some embodiments of the invention, the other performance targets include throughput of the PSS 100. Details of the process-step sequence mining operations and process-step sequence mining systems that can be used, in accordance with aspects of the invention, to analyze the PSS 100 are depicted in FIGS. 2-13 and described in greater detail subsequently herein.

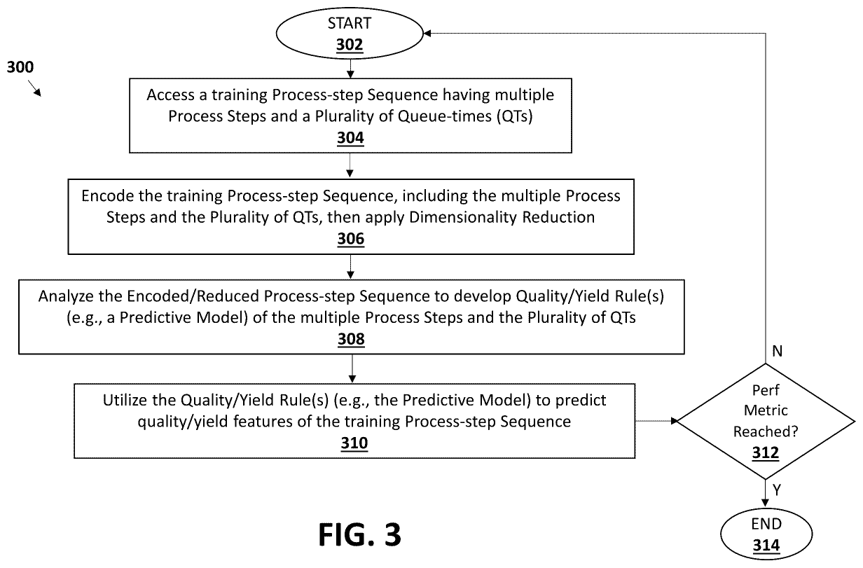

FIG. 2 depicts a block diagram illustrating a PSS mining system 200 that will be trained using a methodology 300 (shown in FIG. 3) in accordance with embodiments of the invention. As shown in FIG. 2, the PSS mining system 200 includes an encoder 204, a dimensionality reduction module 206, and a predictive module 208, configured and arranged as shown. In embodiments of the invention, the predictive module 208 is operable to generate or learn quality/yield rules 210 that govern a PSS-under-evaluation (e.g., the PSS 100 shown in FIG. 1). In embodiments of the invention, the quality/yield rules 210 can be implemented as a predictive model 212 that is generated using machine learning algorithms. In embodiments of the invention, the machine learning algorithms can include natural language processing functionality. PSS training data 202 is applied to the PSS mining system 200 to train the PSS mining system 200 (and specifically the predictive module 208) to, among other things, make quality/yield predictions 214. In some embodiments of the invention, the task to be performed by the predictive module 208 is predicting the yield and the semiconductor product quality, in any combination, that result from a PSS-under-evaluation (e.g., PSS 100 shown in FIG. 1).

A non-limiting example of the training operations that can be applied to the PSS mining system 200 in accordance with aspects of the invention will now be described with reference to the PSS mining system 200 shown in FIG. 2 and the computer-implemented methodology 300 shown in FIG. 3. The methodology 300 begins at block 302 then moves to block 304 where the PSS mining system 200 accesses the PSS training data 202, which includes (similar to the PSS 100 shown in FIG. 1) multiple process steps and multiple QTs. At block 306, the methodology 300 uses the encoder 204 to encode the PSS training data 202, and uses the dimensionality reduction module 206 to reduce the dimensionality of the encoded version of the PSS training data 202. Embodiments of the invention encode the entire PSS training data 202 in order to analyze the entire sequence rather than separately analyzing the individual components (e.g., the individual process steps and the individual QTs) of the PSS training data 202. Encoding the entire PSS training data 202 enables the methodology 300 to apply analysis techniques that reduce the burden of analyzing a large amount of data with combinatorial dependence structures (e.g., thousands of process-steps with as many as a million QTs), which enables the methodology 300 to explore and uncover the rules, conditions, and the like (e.g., quality-related rules/conditions and/or yield-related rules/conditions) that govern the entire PSS training data 202.

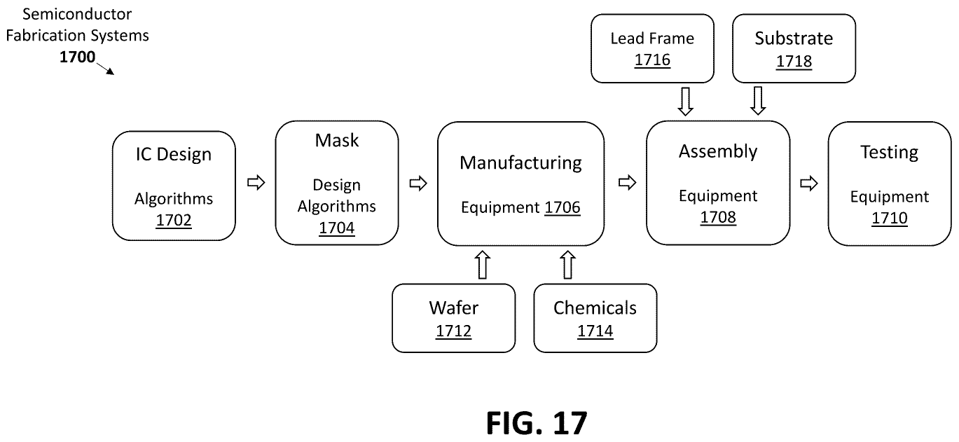

In some embodiments of the invention, the PSS training data 202 is annotated or labeled (i.e., the quality and yield characteristics of the PSS training data 202 are known and provided). In some embodiments of the invention, the PSS training data 202 is not annotated or labeled (i.e., the quality and yield characteristics of the PSS training data 202 are unknown). In some embodiments of the invention, the PSS training data 202 is a combination of annotated/labeled training data and non-annotated/non-labeled training data. The encoder 204 represents the components (i.e., the various process steps and their associated QTs) of the PSS training data 202 as a sequence of symbols. Because the components of the PSS training data 202, taken collectively, have various relationships to the yield and semiconductor product quality produced by the PSS training data 202, the encoded components of the symbol sequence, taken collectively, also have various relationships to the yield and semiconductor product quality produced by the PSS training data 202. Additionally, because the PSS training data 202 is now represented as symbols that have meaning (i.e., various relationships to the yield and semiconductor product quality produced by the PSS training data 202, analysis techniques that draw meaning from symbol sequences (e.g., letters, words, sentences) can be leveraged to manage the large amount of data and combinatorial dependence structures (e.g., data dependency) in the PSS training data 202 of, for example, a semiconductor fabrication system (e.g. semiconductor fabrication system 1700 shown in FIG. 17). Accordingly, the symbol sequence (or encoding sequence) that represents the components (i.e., the various process steps and their associated QTs) of the PSS training data 202 can be applied to the dimensionality reduction module 206, and the dimensionality reduction module 206 can use NLP techniques (e.g., word embeddings) to reduce the dimensionality of the symbol sequence in a manner that could not be accomplished through direct analysis of the PSS training data 202.

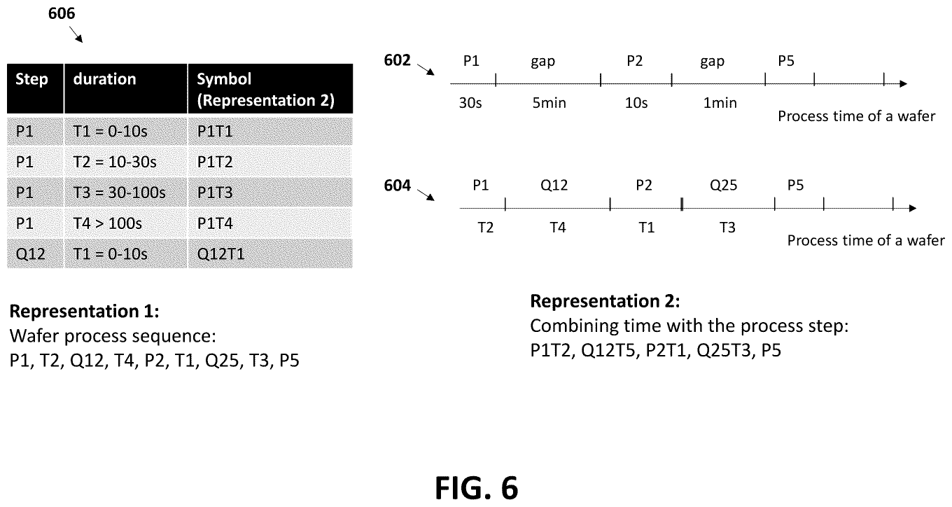

Additional details of how the symbol sequence encoding operations and dimensionality reduction operations at block 306 can be implemented are depicted in FIGS. 6, 7, and 8 and described in greater detail subsequently herein.

The methodology 300 moves to block 308 where the predictive module 208 applies various analysis techniques to the encoded/reduced PSS training data 202 to develop or uncover the quality/yield rules 210 (e.g., the predictive model 212) of the multiple process steps and the plurality of QTs that form the PSS training data 202. In some embodiments of the invention, the predictive module 208 uses machine learning algorithms (including NLP algorithms) to uncover the quality/yield rules 210 and/or the predictive model 212. The machine learning algorithms can learn in a supervised or unsupervised manner depending on whether the PSS training data 202 is labeled or unlabeled. In some embodiments of the invention, the machine learning algorithms utilize clustering techniques to produce clusters that are correlated to yield and/or semiconductor product quality, and to further produce (or predict, or extract) the PSS features (including QTs) that impact yield and/or semiconductor product quality. More specifically, the machine learning algorithms identify (or predict, or extract) respective distinctive features of the clusters with a large proportion of high-quality and low-quality semiconductor products, as well as the distinctive features of the clusters with a large proportion of high yield results and low yield results. At block 310, in some embodiments of the invention, the predictive module 208 infers from the distinctive features of the PSS training data 202 whether the PSS training data 202 is likely to produce, for example, high quality semiconductor products, low quality semiconductor products, high yields, and/or low yields.

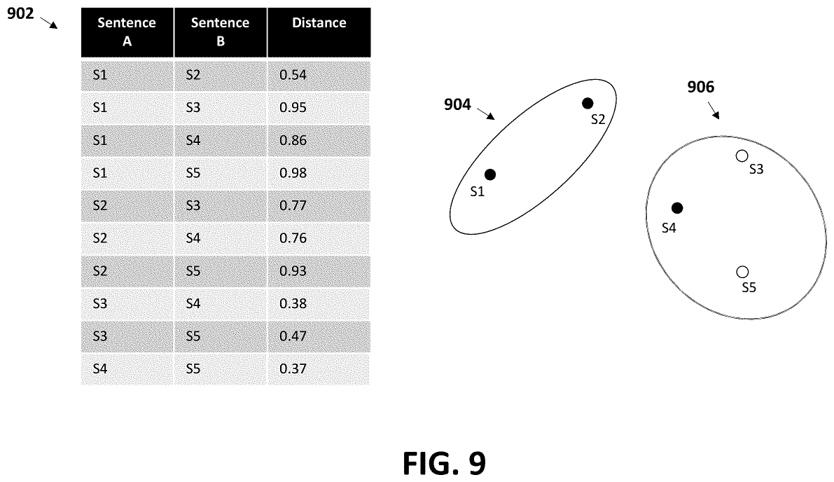

Additional details of how the operations at block 308 and block 310 can be implemented are depicted in FIGS. 9-12B and described in greater detail subsequently herein.

From block 310, the methodology 300 moves to decision block 312 to evaluate a performance metric of the prediction made at block 310. In aspects of the invention, the performance metric can be any suitable metric operable to measure the performance of a model. In some embodiments of the invention, the performance metric is the model accuracy (or modeling accuracy) of the model. Model accuracy is defined as the number of tasks or determinations a model performs correctly divided by the total number of tasks or determinations performed. In aspects of the invention, the ML model can be configured to apply confidence levels (CLs) to its tasks/determinations in order to improve the overall accuracy of the task/determination. When the ML model performs a task or makes a determination for which the value of CL is below a predetermined threshold (TH) (i.e., CL<TH), the task/determination can be classified as having sufficiently low “confidence” to justify a conclusion that the task/determination is not valid. If CL>TH, the task/determination can be considered valid. Many different predetermined TH levels can be provided such that the tasks/determinations with CL>TH can be ranked from the highest CL>TH to the lowest CL>TH, which can further assist in evaluating the similarity or dissimilarity of the modeling accuracy results generated by the different local ML models.

When decision block 312 determines that the prediction accuracy of the PSS mining system 200 is below a predetermined prediction accuracy threshold, the PSS mining system 200 is considered not-trained and the methodology 300 returns to block 302 to run additional iterations of the methodology 300 using additional/new instances of the PSS training data 202. When decision block 312 determines that the prediction accuracy of the PSS mining system 200 is above the predetermined prediction accuracy threshold, the PSS mining system 200 is considered trained and the methodology 300 moves to block 314 and ends.

Additional details of how the operations at block 308, and block 310, and decision block 312 can be implemented are depicted in FIGS. 9-12B and described in greater detail subsequently herein.

FIG. 4 depicts a trained PSS mining system 400 in accordance with aspects of the invention. The trained PSS mining system 400 includes a predictive module 208A, an optimization module 410, and a pattern sequence extraction module 420, configured and arranged as shown. The predictive module 208A is a trained version of the predictive module 208 (shown in FIG. 2). Through training operations (e.g., methodology 300 shown in FIG. 3), encoding and dimensionality reduction operations are incorporated within the predictive module 208A and represented as an encoder 204A and a dimensionality reduction module 206A, where the encoder 204A corresponds in functionality to the encoder 204 (shown in FIG. 2), and where the dimensionality reduction module 206A corresponds in functionality to the dimensionality reduction module 206 (shown in FIG. 2). In embodiments of the invention, the trained PSS mining system 400 analyzes the PSS 100 to generate quality/yield predictions 214A, which correspond to the quality/yield predictions 214 (shown in FIG. 2), except the quality/yield predictions 214A have a prediction accuracy above the previously-described prediction accuracy threshold.

In embodiments of the invention, the optimization module 410 receives the quality/yield predictions 214A and/or other outputs from the predictive module 208A (e.g., extracted features of the PSS 100 that impact quality and/or yield) to perform optimization operations, an example of which is optimizing the tradeoffs between throughput of the PSS 100 and the quality/yield of the PSS 100 (i.e., throughput and quality/yield tradeoffs 412). Another example output of the optimization module 410 is the second example use of a quality/yield prediction depicted in FIG. 1. In embodiments of the invention, the outputs generated by the optimization module 410 can also be provided to the predictive module 208A to provide additional training for the quality/yield rules 210A and/or the predictive model 212A.

In embodiments of the invention, the pattern sequence extraction module 420 receives the quality/yield predictions 214A and/or other outputs from the predictive module 208A (e.g., features of PSS 100 that impact quality and/or yield) to discover the sequences of process steps and the sequences of QTs that are important to quality and/or yield, an example of which is the critical-to-quality (CTQ)/critical-to-yield (CTY) predictions 422. In general, an item, attribute, or action that is CTQ (or CTY) is an item, attribute, or action that has a direct and significant impact on meeting a predetermined standard of quality (or yield). Another example output of the pattern sequence extraction module 420 is the first example use of a quality/yield prediction depicted in FIG. 1. In embodiments of the invention, the outputs generated by the pattern sequence extraction module 420 can also be provided to the predictive module 208A to provide additional training for the quality/yield rules 210A and/or the predictive model 212A.

Operations of the PSS mining system 400 in accordance with aspects of the invention will now be described with reference to the PSS mining system 400 shown in FIG. 4 and the computer-implemented methodology 500 shown in FIG. 5. The methodology 500 begins at block 502 then moves to block 504 where the PSS mining system 400 accesses the PSS 100, which includes the multiple process steps and multiple QTs shown in FIG. 1. At block 506, the methodology 500 uses the encoder 204A to encode the PSS 100, and uses the dimensionality reduction module 206A to reduce the dimensionality of the encoded version of the PSS 100. Embodiments of the invention encode the entire PSS 100 in order to analyze the entire sequence rather than separately analyzing the individual components (e.g., the individual process steps and the individual QTs) of the PSS 100. Encoding the entire PSS 100 enables the methodology 500 to apply analysis techniques that reduce the burden of analyzing a large amount of data with combinatorial dependence structures (e.g., thousands of process-steps with as many as a million QTs), which enables the methodology 500 to explore and uncover the rules, conditions, and the like (e.g., quality-related rules/conditions and/or yield-related rules/conditions) that govern the entire PSS 100.

The encoder 204A represents the components (i.e., the various process steps and their associated QTs) of the PSS 100 as a sequence of symbols. Because the components of the PSS 100, taken collectively, have various relationships to the yield and semiconductor product quality produced by the PSS 100, the encoded components of the symbol sequence, taken collectively, also have various relationships to the yield and semiconductor product quality produced by the PSS 100. Additionally, because the PSS 100 is now represented as symbols that have meaning (i.e., various relationships to the yield and semiconductor product quality produced by the PSS 100, analysis techniques that draw meaning from symbol sequences (e.g., letters, words, sentences) can be leveraged to manage the large amount of data and combinatorial dependence structures (e.g., data dependency) in the PSS 100 of, for example, a semiconductor fabrication system. Accordingly, the symbol sequence (or encoding sequence) that represents the components (i.e., the various process steps and their associated QTs) of the PSS 100 can be applied to the dimensionality reduction module 206A, and the dimensionality reduction module 206A can use NLP techniques (e.g., word embeddings) to reduce the dimensionality of the symbol sequence in a manner that could not be accomplished through direct analysis of the PSS 100.

Additional details of how the symbol sequence encoding operations and dimensionality reduction operations at block 506 can be implemented are depicted in FIGS. 6, 7, and 8 and described in greater detail subsequently herein.

The methodology 500 moves to block 508 where the predictive module 208A applies quality/yield rules 210A (e.g., the predictive model 212A) to the encoded/reduced PSS 100 to generate the quality/yield predictions 214A. In some embodiments of the invention, the predictive module 208A uses machine learning algorithms (including NLP algorithms) to generate the quality/yield predictions 214A. In some embodiments of the invention, the machine learning algorithms utilize clustering techniques to place the PSS 100 into a cluster (e.g., clusters that are correlated to yield and/or semiconductor product quality), and to further produce (or predict, or extract) the features of the PSS 100 (including QTs) that impact yield and/or semiconductor product quality. More specifically, the machine learning algorithms uses the clusters to identify (or predict, or extract) respective distinctive features of the PSS 100 that correlate to a large proportion of high-quality and/or low-quality semiconductor products, as well as the distinctive features of the PSS100 that correlate to a large proportion of high yield results and low yield results. At block 508, in some embodiments of the invention, the predictive module 208A infers from the distinctive features of the PSS 100 whether the PSS 100 is likely to produce, for example, high quality semiconductor products, low quality semiconductor products, high yields, and/or low yields. At block 508, in some embodiments of the invention, the predictive module 208A infers from the distinctive features of the PSS 100 whether the PSS 100 is likely to produce, for example, high quality semiconductor products, low quality semiconductor products, high yields, and/or low yields.

At block 510, the optimization module 410 receives the quality/yield predictions 214A and/or other outputs from the predictive module 208A (e.g., features of PSS 100 that impact quality and/or yield) to perform optimization operations, an example of which is optimizing the tradeoffs between throughput, yield, and/or quality of the PSS 100 (e.g., throughput and quality/yield tradeoffs 412). Another example of the optimization operations performed at block 510 is the second example use of a quality/yield prediction depicted in FIG. 1. At block 512, the pattern sequence extraction module 420 receives the quality/yield predictions 214A and/or other outputs from the predictive module 208A (e.g., features of PSS 100 that impact quality and/or yield) to discover the sequences of process steps and the sequences of QTs that are important to quality and/or yield, an example of which is the CTQ/CTY predictions 422. Another example output of the pattern sequence extraction module 420 is the first example use of a quality/yield prediction depicted in FIG. 1.

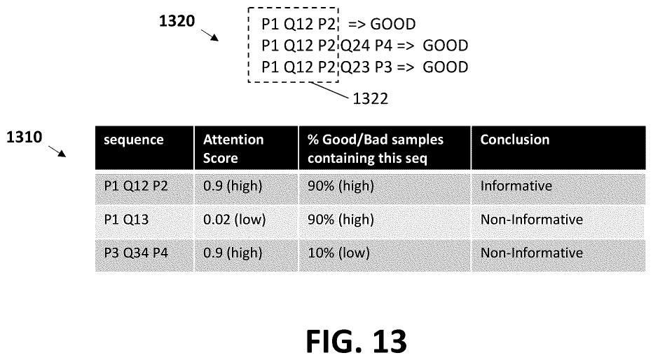

Additional details of how the pattern sequence extraction module 420 (shown in FIG. 4) and the operations at block 512 (shown in FIG. 5) can be implemented are depicted in FIG. 13 and described in greater detail subsequently herein.

Turning now to non-limiting examples of how aspects of the methodology 300 (shown in FIG. 3) can be implemented, additional details of how the symbol sequence encoding operations at block 306 of the methodology 300 can be implemented will now be described with reference to FIG. 6. FIG. 6 depicts a first timeline diagram 602, a second timeline diagram 604, and a table 606, configured and arranged as shown. As shown in the first timeline diagram 602, process steps can be represented by the symbols P1, P2, . . . , P1000, were each symbols corresponds to and represents an individual process step in the process-step sequence (e.g., PSS 100 shown in FIG. 1). As shown in the second timeline diagram 604, the gap or wait time or queue time between two process-steps can be represented by the symbols Q1/2, Q2/3, . . . , Q999/1000 (e.g., QT-1/2, QT-2/3, QT-3/4, QT-4/5, QT-5/6, shown in FIG. 1). The time spent in each of the process-step or QT can be represented by the symbols T1, T2, . . . , Tn, where T1, T2 are time values that have been discretized and assigned symbols for each of the buckets, where there are n buckets. In applied mathematics, discretization is the process of transferring continuous functions, models, variables, and equations into discrete counterparts. Discretization is carried out as a first step toward making time values suitable for numerical evaluation and implementation on digital computers. If the time ranges from a few seconds to a few hours or days, discretization can be done at logarithmic scale then converted into symbols. Table 606 illustrates process-step and QT symbols in column 1; encoded time durations in column 2; and symbol representations in which each process-step representation and/or QT representation is combined with its associated time symbol. As shown, Representation 1 is used in columns 1 and 2 of the table 606; and Representation 2 is used in column 3 of the table 606.

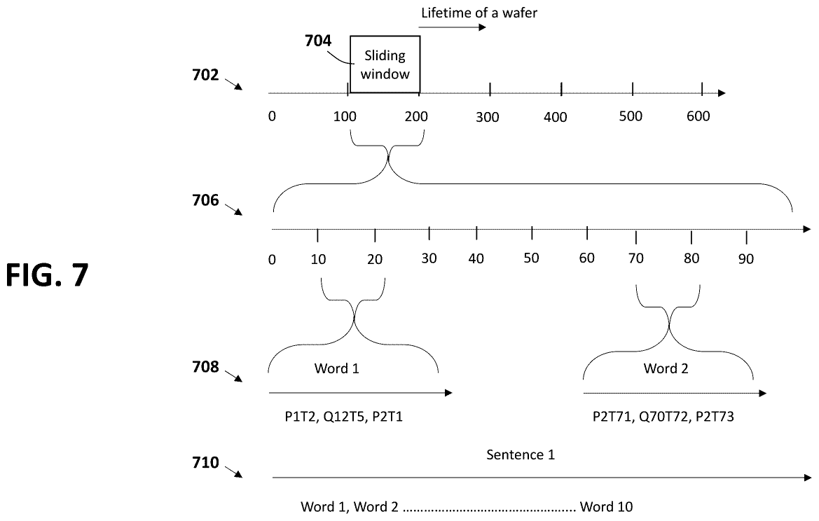

Additional details of how dimensionality reduction operations at block 306 of the methodology 300 can be implemented will now be described with reference to FIG. 7. FIG. 7 depicts a first timeline diagram 702; a second timeline diagram 706 that provides additional details of a portion of the first timeline diagram 702; a third timeline diagram 708 that provides additional details of a portion of the second timeline diagram 706; and a fourth timeline diagram 710 that provides additional details of the second timeline diagram 706. In accordance with embodiments of the invention, the discretized symbols are considered characters in a specialized type of language domain. In aspects of the invention, the encoding operation transforms a PSS into symbols that are part of unique type of language domain referred to herein as a PSS language domain. In a natural language processing domain, sequences of symbols in the form of letters, words, and sentences are evaluated to derive their meaning in a given natural language such as the English language. For example, in the English language, the sequence of letters “I ran away and hid when I saw the tiger in the woods” has a different meaning from the sequence of letters “I stayed to confront the threat presented by the tiger when I saw the tiger in the woods.” In the novel PSS language domain, in accordance with aspects of the invention, the components of an entire PSS are converted to (or encoded into) symbols, and sequences of symbols are evaluated to understand how, for example, a change to a given symbol (e.g., an increase/decrease in QT) or a change to a given symbol sequence (e.g., the order of certain process-steps) impacts the quality or yield of semiconductor products produced by the entire PSS.

Continuing with FIG. 7, the symbols are aggregated over a sliding window 704 on the temporal axis of the first timeline diagram 702 to form words (e.g., Word 1; and Word 2) of length (w) on the temporal axes of the second timeline diagram 706 and the third timeline diagram 708. On the temporal axis of the fourth timeline diagram 710, each wafer is now represented in the form of multiple sentences over the lifetime of the PSS 100. These sentences are passed on to a word embedding module (e.g., Word2Vec, BoW, and the like), which form embeddings of each of the words in a lower dimensional space in such a way that similar words belong closer together in the embedded space. Two wafers that have similar process-step sequences will be automatically placed closer together based on the words that make up their lifetime.

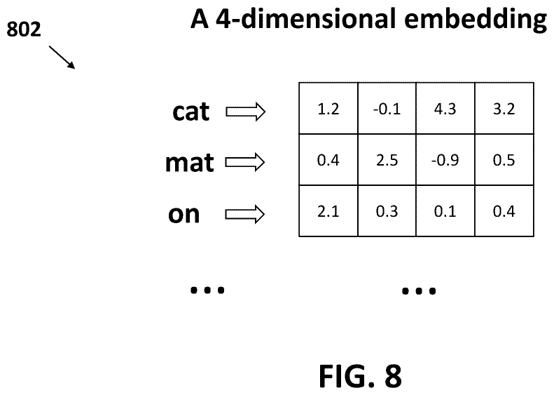

FIG. 8 illustrates an example word embedding 802 that can be used in connection with implementing aspects of the invention. In general, neural network models take vectors (i.e., an array of numbers) as inputs. Where the inputs are natural language symbols, token/word vectorization refers to techniques that extract information from the natural language symbol corpus and associate to each word of the natural language symbol corpus a vector. For example, the word “P1T2, Q12T5, P2T1” (shown in FIG. 7) in the disclosed PSS language can be associated with the vector (1, 4, −3, 2). This value can be computed using a suitable vectorization algorithm that takes into account the word's context.

Embeddings are a way to use an efficient, dense vector-based representation in which similar words have a similar encoding. In general, an embedding is a dense vector of floating-point values. An embedding is an improvement over the more traditional bag-of-word model encoding schemes where large sparse vectors are used to represent each word or to score each word within a vector to represent an entire vocabulary. Such representations are considered to be sparse because the vocabularies (e.g., in the PSS language domain) can be vast, and a given word sequence or encoded PSS sequence would be represented by a large vector having mostly zero token values. Instead, in an embedding, words are represented by dense vectors where a vector represents the projection of the word into a continuous vector space. The length of the vector is a parameter that must be specified. However, the values of the embeddings are trainable parameters (i.e., weights learned by the model during training in the same way a model learns weights for a dense layer). More specifically, the position of a word within the vector space of an embedding is learned from text in the PSS language domain and is based on the words that surround the word when it is used. The position of a word in the learned vector space of the word embedding is referred to as its embedding. Small datasets can have word embeddings that are as small as 8-dimensional, while larger datasets can have word embeddings as large as 1024-dimensions. A higher dimensional embedding can capture fine-grained relationships between words but takes more data to learn.

FIG. 8 depicts an example diagram of a word embedding 802 in an English language domain. As shown in FIG. 8, each word is represented as a 4-dimensional vector of floating-point values. Another way to think of the word embedding 802 is as “lookup table.” After the weights have been learned, each word can be encoded by looking up the dense vector it corresponds to in the table. The Embedding layer (or lookup table) maps from integer indices (which stand for specific words) to dense vectors (their embeddings). The dimensionality (or width) of the embedding is a parameter that can be selected to match the task for which it is designed. When an embedding layer is created, the weights for the embeddings are randomly initialized (just like any other layer), During training, the weights are gradually adjusted via back-propagation training techniques. Once trained, the learned word embeddings will roughly encode similarities between words (as they were learned for the specific problem on which the model is trained).

Additional details of how the operations at block 308 and block 310 can be implemented are depicted in FIGS. 9-12B and described in greater detail subsequently herein. As previously noted herein, at block 308 of the methodology 300 the predictive module 208 applies various analysis techniques to the encoded/reduced PSS training data 202 to develop or uncover the quality/yield rules 210 (e.g., the predictive model 212) of the multiple process steps and the plurality of QTs that form the PSS training data 202. In some embodiments of the invention, the predictive module 208 uses machine learning algorithms (including NLP algorithms) to uncover the quality/yield rules 210 and/or the predictive model 212. The machine learning algorithms can learn in a supervised or unsupervised manner depending on whether the PSS training data 202 is labeled or unlabeled.

In some embodiments of the invention, the predictive module 208 can utilize clustering to produce clusters of PSS that are correlated to yield and/or semiconductor product quality, and to further produce (or predict, or extract) the PSS features (including QTs) that impact yield and/or semiconductor product quality. More specifically, the machine learning algorithms of the predictive module 208 identify (or predict, or extract) respective distinctive features of the clusters with a large proportion of high-quality and low-quality semiconductor products, as well as the distinctive features of the clusters with a large proportion of high yield results and low yield results.

FIG. 9 depicts a result of using known clustering techniques to cluster sentences (e.g., as shown in FIG. 7) of the PSS language domain. FIG. 9 depicts a table 902 and two clusters 904, 906 that can be drawing from the relative distances of the five data points, S1, S2, S3, S4, S5 shown in the table 902. As shown, cluster 902 can be drawn around S1 and S2, and cluster 904 can be drawing around S3, S4, S5. The operations to generate the table can include defining distance metrics to build the graph, where the distance metric can be, for example, cosine similarity and/or BLEU (BiLingual Evaluation Understudy) score. The operations further include applying various clustering algorithms such as k-mean, hierarchical cluster, or graph-based clustering.

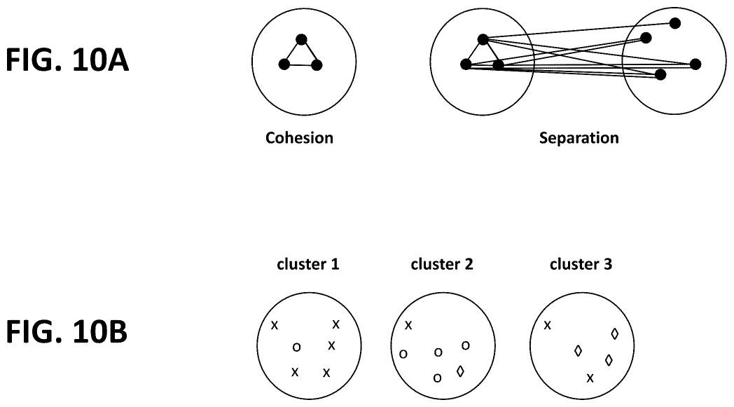

FIG. 10A and FIG. 10B depict additional examples of cluster quality metrics that can be used to perform the clustering operations described herein. In FIG. for unsupervised learning, cohesion, separation, and silhouette coefficient (uses a combination of cohesion and separation) can be used to generate cluster quality metrics for unsupervised clustering. Cluster cohesion determines how closely related the objects in a cluster are. For instance an unsupervised cluster evaluator that measures cohesion could analyze the distance between the data points in the cluster (e.g., table 902 shown in FIG. 9). Cluster separation determines how distinct a cluster is from other clusters. Cluster separation is concerned with how far clusters are away from one another.

FIG. 10B illustrates the use of an external evaluation criterion for cluster quality in supervised clustering. Supervised clustering techniques measures how well the clustering algorithms' created structure matches to some external data. For instance, if the class labels for a given set of data are known, a clustering algorithm could be used to group the data and compare these clusters to the labels that were given. This requires external data and so it is otherwise known as external indices because it uses information that is not in the data set. Some common measures include entropy, which measures the degree to which each cluster consists of objects of a single class; purity, which is similar to entropy in that it also measures the degree of homogeneity of each cluster; and precision, which is the fraction of a cluster that consists of objects of a specified class. FIG. 10B illustrates an example of how purity can be used as an external evaluation criterion for cluster quality in supervised clustering. Majority class and the number of members of the majority class for the three clusters shown are: x, 5 (cluster 1); o, 4 (cluster 2); and ⋄, 3 (cluster 3). Purity is (1/17)×(5+4+3)≈0.71.

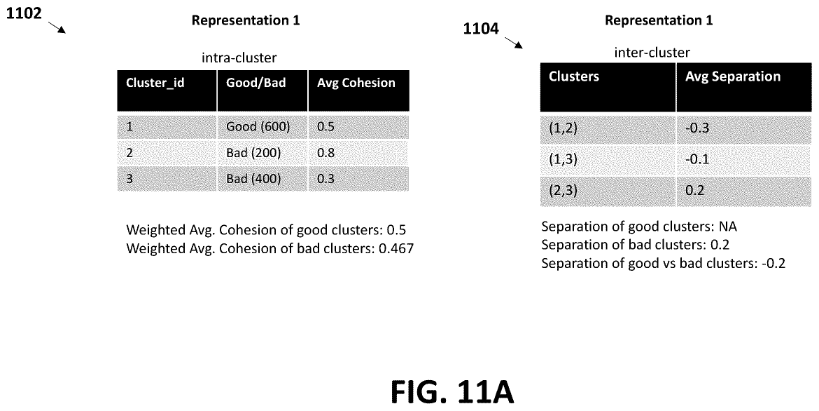

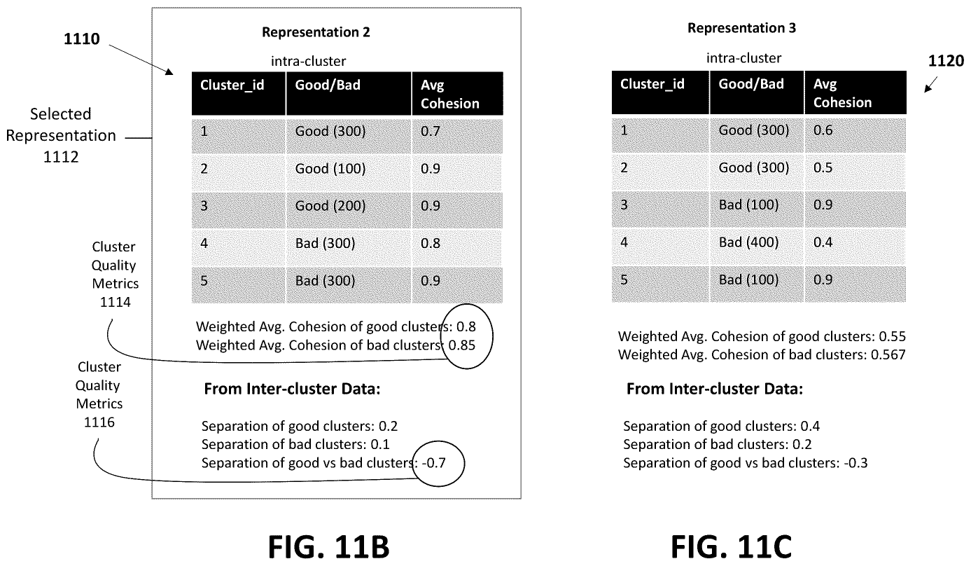

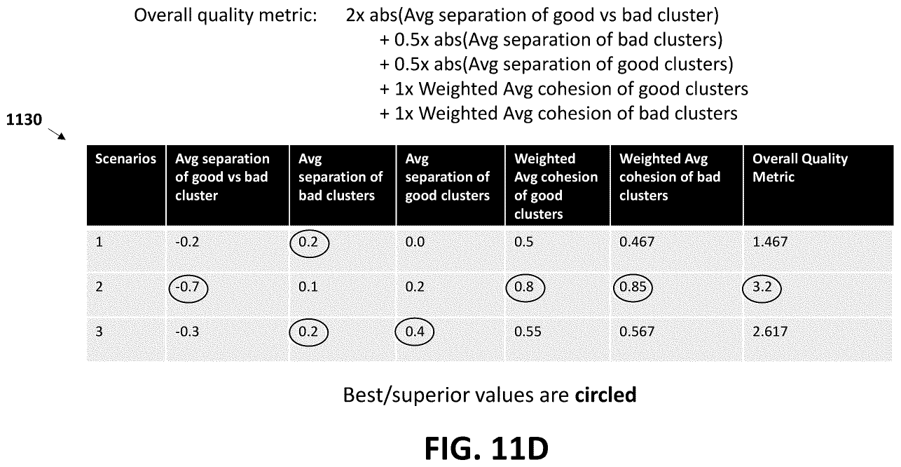

FIGS. 11A-11D examples of unsupervised learning techniques for, in accordance with aspects of the invention, selecting a cluster quality metric, and further in accordance with aspects of the invention, optimizing over clustering methods and associated parameters to obtain the best/superior cluster quality metric. In accordance with embodiments of the invention, once generated, sentence clusters are evaluated; and the clusters that perform best on quality and yield predictions are identified. Comparisons among the clusters are done by defining a level of n-gram matching. For example, for sparse data, 2-gram coverage would be desired; and for dense data, higher n-gram coverage can be computed. In embodiments of the invention, clusters are generated based on a cluster quality metric, such as cohesion, separation and silhouette coefficients.

FIGS. 11A, 11B, and 11C depict an example of how the performance metric evaluation at block 310 and decision block 312 of the methodology 300 shown in FIG. 3 can be implemented in accordance with embodiments of the invention. More specifically, FIGS. 11A, 11B, and 11C depict an example of how a clustering representation can be selected based on an evaluation of clustering quality metrics in accordance with aspects of the invention. Further in accordance with aspects of the invention, the parameters of words and sentences (e.g., as shown in FIGS. 6 and 7) used to form the selected representation (e.g., Representation 2 shown in FIG. 11B), as well as the parameters of the clustering techniques used to form the selected representation (e.g., Representation 2 shown in FIG. 11B), are identified during training as parameters or features that perform well on the task to be performed by the predictive module 208 using the quality/yield rules 210A and/or the predictive model 212A. Although FIGS. 11A, 11B, and 11C depict three example representations (Representation 1, Representation 2, Representation 3), it is understood that, in practice, any number of representations and representation types will be generated and compared as part of the training methodology 300.

FIG. 11A depicts Representation 1, which depicts an intra-cluster table 1102 and an inter-cluster table 1104 that display results of a set of clustering analyses attempted during training of the predictive module 208. The intra-cluster table 1102 depicts the cluster ID, the good/bad status of the cluster, and the average cohesion computation of the cluster. The notation “Good (600)” identifies that a total of 600 samples are in the cluster, and further identifies that the cluster has been identified as good. The inter-cluster table 1104 depicts cluster comparisons in column 1, along with the average separation of the compared clusters in column 2.

FIGS. 11B and 11C depict Representation 2 and Representation 3, respectively. For each of Representation 2 and Representation 3 an intra-cluster table 1110, 1120 is shown, but only the computations that result from the corresponding inter-cluster table is shown. In accordance with embodiments of the invention, as part of the training methodology 300 (shown in FIG. 3), Representation 1, Representation 2, and Representation 3, are compared, and Representation 2 (shown in FIG. 11B) is identified as a selected representation 1112 having superior clustering performance over Representation 1 and Representation 3 based on superior cluster quality metrics 1114, 1116. In some embodiments of the invention, various CL analyses (e.g., block 312 and decision block 314 of the methodology 300 shown in FIG. 3) can be applied to the selected representation 1112 to determine whether the predictive module 208 is performing sufficiently well to end training and begin using the predictive module (e.g., as predictive module 208A shown in FIG. 4).

FIG. 11D depicts a table 1130 illustrating a non-limiting example of generating an overall cluster quality metric by weighting different cluster quality metrics from different sources in accordance with embodiments of the invention. In the example depicted in FIG. 11D, five different cluster quality metrics are evaluated, however, embodiments of the invention are not limited to the use of five cluster quality metrics. Additionally, the technique for generating an overall cluster quality metric by weighting different cluster quality metrics from different sources can, in accordance with aspects of the invention, be applied to either unsupervised and/or supervised training scenarios.

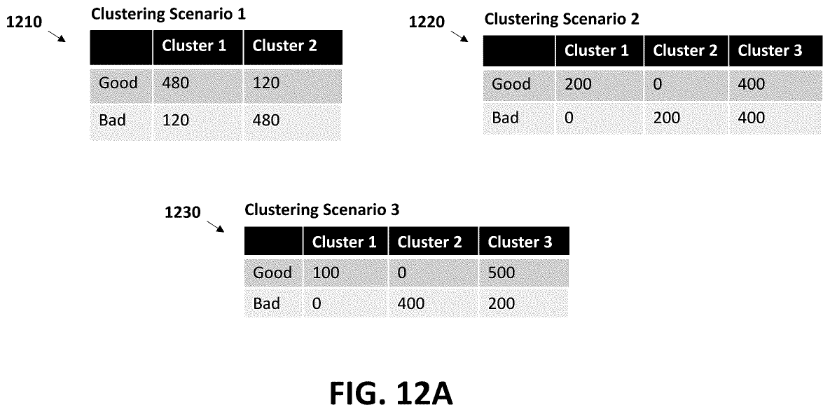

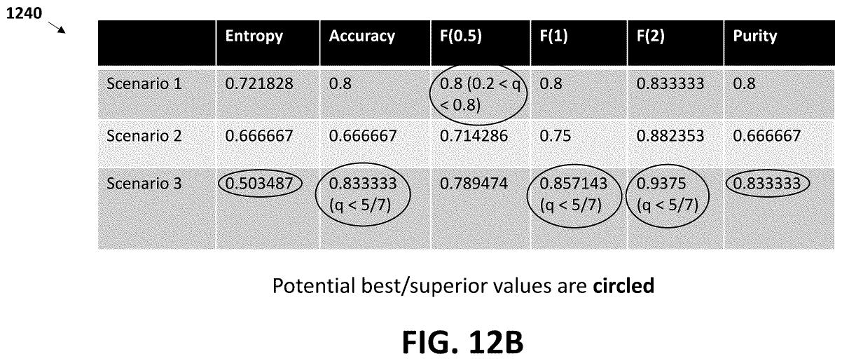

FIGS. 12A, 12B depict examples of supervised learning techniques for, in accordance with aspects of the invention, selecting a cluster quality metric, and further in accordance with aspects of the invention, optimizing over clustering methods and associated parameters to obtain the best/superior cluster quality metric. As previously noted, supervised learning techniques are used when large quantities of labeled data (e.g., labels that identify good quality/yield results and bad quality/yield results) is available. In general, good wafers should have similar processing steps, and bad wafers should be further away from the feature space/order of processing steps of the good wafers. In embodiments of the invention, clusters will be generated for each of the good and bad wafers independently, and preferably with no/low overlap between good and bad wafers. Comparisons among the clusters are done by defining a level of n-gram matching. For example, for sparse data, 2-gram coverage would be desired; and for dense data, higher n-gram can be computed.

FIG. 12A depicts tables 1210, 1220, 1230 representing results from three clustering scenarios (Clustering Scenario 1; Clustering Scenario 2; and Clustering Scenario 3). For example, table 1210 identifies that Cluster 1 produces 480 good wafers and 120 bad wafers; and further identifies that Cluster 2 produces 120 good wafers and 480 bad wafers. Table 1220 identifies that Cluster 1 produces 200 good wafers and zero (0) bad wafers; Cluster 2 produces zero (0) good wafers and 200 bad wafers; and Cluster 3 produces 400 good wafers and 400 bad wafers. Table 1230 identifies that Cluster 1 produces 100 good wafers and zero (0) bad wafers; Cluster 2 produces zero (0) good wafers and 400 bad wafers; and Cluster 3 produces 500 good wafers and 200 bad wafers.

FIG. 12B depicts a table 1240 that illustrates a non-limiting example of identifying and selecting a cluster evaluation technique by applying various cluster evaluation techniques to the various clustering scenarios depicted in FIG. 12A, and selecting the combination of Clustering Scenario (Clustering Scenario 1, Clustering Scenario 2, Clustering Scenario 3) and cluster evaluation technique (entropy, accuracy, F(0.5), F(1), F(2), purity) that provides best or superior results. In the example depicted in FIG. 12B, six different cluster evaluation techniques are evaluated, however, embodiments of the invention are not limited to the use of six cluster evaluation techniques. The choice of which Clustering Scenario and cluster evaluation technique combination is best or superior depends on the desired cluster quality metric. In embodiments of the invention, the selection of the Clustering Scenario and cluster evaluation technique combination or combinations can be performed as a task of the training methodology 300 (shown in FIG. 3). Additionally, the selection of the Clustering Scenario and cluster evaluation technique combination or combinations can, in accordance with aspects of the invention, be performed in supervised and/or unsupervised training scenarios.

Additional details of how the pattern sequence extraction module 420 (shown in FIG. 4) and the operations at block 512 of the methodology 500 (shown in FIG. 5) can be implemented are depicted in FIG. 13. FIG. 13 depicts a table 1310 illustrating using an attention method of performing the pattern sequence extraction operations of the pattern sequence extraction module 420; and further depicts a diagram 1320 illustrating the use of clustering association rules to perform the pattern sequence extraction operations of the pattern sequence extraction module 420.

For the clustering association rules approach, important good sequences in the PSS 202 are identified by using association rules to find sequence patterns in the PSS 202 that are specific to good clusters only and are not in any all bad or mixed good/bad clusters. For example, in the diagram 1320, the sequence P1, Q12, P2 (identified by reference number 1322) is found only in good clusters. Accordingly, the sequence P1, Q12, P2 is included among the CTQ/CTY predictions 422 shown in FIG. 4. Additionally, important bad sequences in the PSS 202 are identified by using the association rules to find sequence patterns in the PSS 202 that are specific to bad clusters only and are not in any all good or mixed good/bad clusters. The important bad sequences in the PSS 202 can be compared to the good sequences as another check to further confirm that the identified good sequences are in fact good sequences. Similarly, important good sequences in the PSS 202 can be compared to the bad sequences as another check to further confirm that the identified bad sequences are in fact bad sequences.

For the attention method (classification scenario), a classifier is applied to labeled data of the predictive model 212A to extract important process/gap sequences. The classifier identifies features receiving higher attention to identify a list of n-grams with preserving order that lead to Good/Bad wafers; and to identify which n-gram receives larger weights for Good/Bad classes. In embodiments of the invention, the classifier includes makes use of an attention mechanism. In the context of neural networks, an attention mechanism is a technique that electronically mimics human cognitive attention. The effect enhances the important parts of the input data and fades out the rest such that the network devotes more computing power on that small but important part of the data. The part of the data that is more important than other parts of the data depends on the context and is learned through training data by gradient descent. Thus, the attention mechanism weighs the relevance of every other input and draws information from them accordingly to produce the output.

Additional details of machine learning techniques that can be used to implement aspects of the invention disclosed herein will now be provided. The various types of computer control functionality of the processors described herein can be implemented using machine learning and/or natural language processing techniques. In general, machine learning techniques are run on so-called “neural networks,” which can be implemented as programmable computers configured to run sets of machine learning algorithms and/or natural language processing algorithms. Neural networks incorporate knowledge from a variety of disciplines, including neurophysiology, cognitive science/psychology, physics (statistical mechanics), control theory, computer science, artificial intelligence, statistics/mathematics, pattern recognition, computer vision, parallel processing and hardware (e.g., digital/analog/VLSI/optical).

The basic function of neural networks and their machine learning algorithms is to recognize patterns by interpreting unstructured sensor data through a kind of machine perception. Unstructured real-world data in its native form (e.g., images, sound, text, or time series data) is converted to a numerical form (e.g., a vector having magnitude and direction) that can be understood and manipulated by a computer. The machine learning algorithm performs multiple iterations of learning-based analysis on the real-world data vectors until patterns (or relationships) contained in the real-world data vectors are uncovered and learned. The learned patterns/relationships function as predictive models that can be used to perform a variety of tasks, including, for example, classification (or labeling) of real-world data and clustering of real-world data. Classification tasks often depend on the use of labeled datasets to train the neural network (i.e., the model) to recognize the correlation between labels and data. This is known as supervised learning. Examples of classification tasks include identifying objects in images (e.g., stop signs, pedestrians, lane markers, etc.), recognizing gestures in video, detecting voices, detecting voices in audio, identifying particular speakers, transcribing speech into text, and the like. Clustering tasks identify similarities between objects, which they group according to those characteristics in common and which differentiate them from other groups of objects. These groups are known as “clusters.”

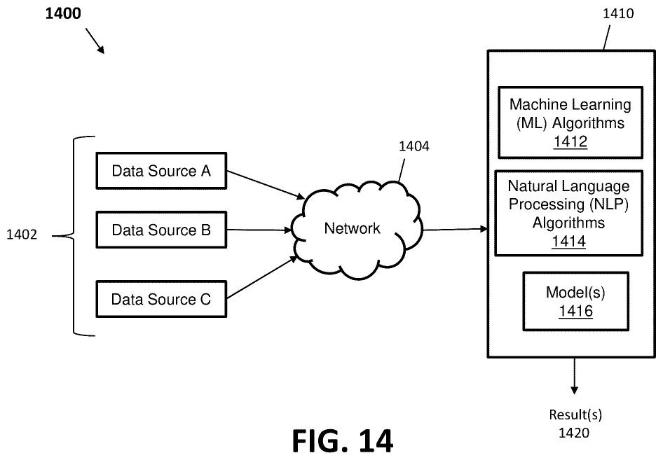

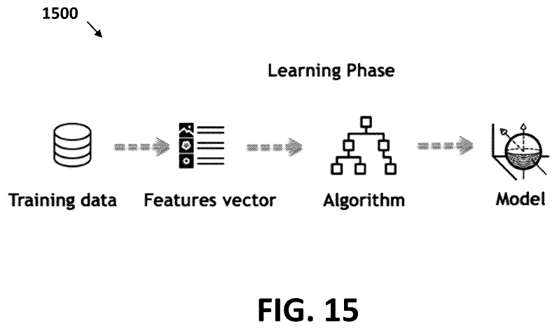

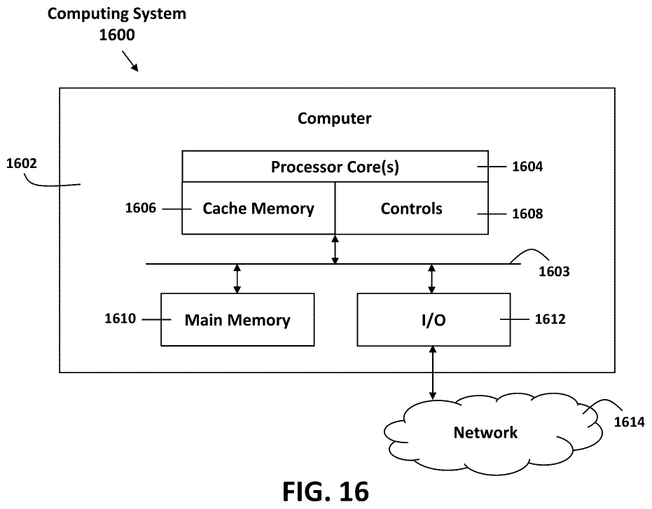

An example of machine learning techniques that can be used to implement aspects of the invention will be described with reference to FIGS. 14 and 15. Machine learning models configured and arranged according to embodiments of the invention will be described with reference to FIG. 14. Detailed descriptions of an example computing system and network architecture capable of implementing one or more of the embodiments of the invention described herein will be provided with reference to FIG. 16.

FIG. 14 depicts a block diagram showing a classifier system 1400 capable of implementing various aspects of the invention described herein. More specifically, the functionality of the system 1400 is used in embodiments of the invention to generate various models and/or sub-models that can be used to implement computer functionality in embodiments of the invention. The system 1400 includes multiple data sources 1402 in communication through a network 1404 with a classifier 1410. In some aspects of the invention, the data sources 1402 can bypass the network 1404 and feed directly into the classifier 1410. The data sources 1402 provide data/information inputs that will be evaluated by the classifier 1410 in accordance with embodiments of the invention. The data sources 1402 also provide data/information inputs that can be used by the classifier 1410 to train and/or update model(s) 1416 created by the classifier 1410. The data sources 1402 can be implemented as a wide variety of data sources, including but not limited to, sensors configured to gather real time data, data repositories (including training data repositories), and outputs from other classifiers. The network 1404 can be any type of communications network, including but not limited to local networks, wide area networks, private networks, the Internet, and the like.

The classifier 1410 can be implemented as algorithms executed by a programmable computer such as a processing system 1600 (shown in FIG. 16). As shown in FIG. 14, the classifier 1410 includes a suite of machine learning (ML) algorithms 1412; natural language processing (NLP) algorithms 1414; and model(s) 1416 that are relationship (or prediction) algorithms generated (or learned) by the ML algorithms 1412. The algorithms 1412, 1414, 1416 of the classifier 1410 are depicted separately for ease of illustration and explanation. In embodiments of the invention, the functions performed by the various algorithms 1412, 1414, 1416 of the classifier 1410 can be distributed differently than shown. For example, where the classifier 1410 is configured to perform an overall task having sub-tasks, the suite of ML algorithms 1412 can be segmented such that a portion of the ML algorithms 1412 executes each sub-task and a portion of the ML algorithms 1412 executes the overall task. Additionally, in some embodiments of the invention, the NLP algorithms 1414 can be integrated within the ML algorithms 1412.

The NLP algorithms 1414 text recognition functionality that allows the classifier 1410, and more specifically the ML algorithms 1412, to receive natural language data (e.g., text written as English alphabet symbols) and apply elements of language processing, information retrieval, and machine learning to derive meaning from the natural language inputs and potentially take action based on the derived meaning. The NLP algorithms 1414 used in accordance with aspects of the invention can also include speech synthesis functionality that allows the classifier 1410 to translate the result(s) 1420 into natural language (text and audio) to communicate aspects of the result(s) 1420 as natural language communications.

The NLP and ML algorithms 1414, 1412 receive and evaluate input data (i.e., training data and data-under-analysis) from the data sources 1402. The ML algorithms 1412 include functionality that is necessary to interpret and utilize the input data's format. For example, where the data sources 1402 include image data, the ML algorithms 1412 can include visual recognition software configured to interpret image data. The ML algorithms 1412 apply machine learning techniques to received training data (e.g., data received from one or more of the data sources 1402) in order to, over time, create/train/update one or more models 1416 that model the overall task and the sub-tasks that the classifier 1410 is designed to complete.

Referring now to FIGS. 14 and 15 collectively, FIG. 15 depicts an example of a learning phase 1500 performed by the ML algorithms 1412 to generate the above-described models 1416. In the learning phase 1500, the classifier 1410 extracts features from the training data and converts the features to vector representations that can be recognized and analyzed by the ML algorithms 1412. The feature vectors are analyzed by the ML algorithm 1412 to “classify” the training data against the target model (or the model's task) and uncover relationships between and among the classified training data. Examples of suitable implementations of the ML algorithms 1412 include but are not limited to neural networks, support vector machines (SVMs), logistic regression, decision trees, hidden Markov Models (HMMs), etc. The learning or training performed by the ML algorithms 1412 can be supervised, unsupervised, or a hybrid that includes aspects of supervised and unsupervised learning. Supervised learning is when training data is already available and classified/labeled. Unsupervised learning is when training data is not classified/labeled so must be developed through iterations of the classifier 1410 and the ML algorithms 1412. Unsupervised learning can utilize additional learning/training methods including, for example, clustering, anomaly detection, neural networks, deep learning, and the like.

When the models 1416 are sufficiently trained by the ML algorithms 1412, the data sources 1402 that generate “real world” data are accessed, and the “real world” data is applied to the models 1416 to generate usable versions of the results 1420. In some embodiments of the invention, the results 1420 can be fed back to the classifier 1410 and used by the ML algorithms 1412 as additional training data for updating and/or refining the models 1416.

In aspects of the invention, the ML algorithms 1412 and the models 1416 can be configured to apply confidence levels (CLs) to various ones of their results/determinations (including the results 1420) in order to improve the overall accuracy of the particular result/determination. When the ML algorithms 1412 and/or the models 1416 make a determination or generate a result for which the value of CL is below a predetermined threshold (TH) (i.e., CL<TH), the result/determination can be classified as having sufficiently low “confidence” to justify a conclusion that the determination/result is not valid, and this conclusion can be used to determine when, how, and/or if the determinations/results are handled in downstream processing. If CL>TH, the determination/result can be considered valid, and this conclusion can be used to determine when, how, and/or if the determinations/results are handled in downstream processing. Many different predetermined TH levels can be provided. The determinations/results with CL>TH can be ranked from the highest CL>TH to the lowest CL>TH in order to prioritize when, how, and/or if the determinations/results are handled in downstream processing.

In aspects of the invention, the classifier 1410 can be configured to apply confidence levels (CLs) to the results 1420. When the classifier 1410 determines that a CL in the results 1420 is below a predetermined threshold (TH) (i.e., CL<TH), the results 1420 can be classified as sufficiently low to justify a classification of “no confidence” in the results 1420. If CL>TH, the results 1420 can be classified as sufficiently high to justify a determination that the results 1420 are valid. Many different predetermined TH levels can be provided such that the results 1420 with CL>TH can be ranked from the highest CL>TH to the lowest CL>TH.

The functions performed by the classifier 1410, and more specifically by the ML algorithm 1412, can be organized as a weighted directed graph, wherein the nodes are artificial neurons (e.g. modeled after neurons of the human brain), and wherein weighted directed edges connect the nodes. The directed graph of the classifier 1410 can be organized such that certain nodes form input layer nodes, certain nodes form hidden layer nodes, and certain nodes form output layer nodes. The input layer nodes couple to the hidden layer nodes, which couple to the output layer nodes. Each node is connected to every node in the adjacent layer by connection pathways, which can be depicted as directional arrows that each has a connection strength. Multiple input layers, multiple hidden layers, and multiple output layers can be provided. When multiple hidden layers are provided, the classifier 1410 can perform unsupervised deep-learning for executing the assigned task(s) of the classifier 1410.

Similar to the functionality of a human brain, each input layer node receives inputs with no connection strength adjustments and no node summations. Each hidden layer node receives its inputs from all input layer nodes according to the connection strengths associated with the relevant connection pathways. A similar connection strength multiplication and node summation is performed for the hidden layer nodes and the output layer nodes.

The weighted directed graph of the classifier 1410 processes data records (e.g., outputs from the data sources 1402) one at a time, and it “learns” by comparing an initially arbitrary classification of the record with the known actual classification of the record. Using a training methodology knows as “back-propagation” (i.e., “backward propagation of errors”), the errors from the initial classification of the first record are fed back into the weighted directed graphs of the classifier 1410 and used to modify the weighted directed graph's weighted connections the second time around, and this feedback process continues for many iterations. In the training phase of a weighted directed graph of the classifier 1410, the correct classification for each record is known, and the output nodes can therefore be assigned “correct” values. For example, a node value of “1” (or 0.9) for the node corresponding to the correct class, and a node value of “0” (or 0.1) for the others. It is thus possible to compare the weighted directed graph's calculated values for the output nodes to these “correct” values, and to calculate an error term for each node (i.e., the “delta” rule). These error terms are then used to adjust the weights in the hidden layers so that in the next iteration the output values will be closer to the “correct” values.

FIG. 16 illustrates an example of a computer system 1600 that can be used to implement any of the computer-based components of the various embodiments of the invention described herein. The computer system 1600 includes an exemplary computing device (“computer”) 1602 configured for performing various aspects of the content-based semantic monitoring operations described herein in accordance aspects of the invention. In addition to computer 1602, exemplary computer system 1600 includes network 1614, which connects computer 1602 to additional systems (not depicted) and can include one or more wide area networks (WANs) and/or local area networks (LANs) such as the Internet, intranet(s), and/or wireless communication network(s). Computer 1602 and additional system are in communication via network 1614, e.g., to communicate data between them.

Exemplary computer 1602 includes processor cores 1604, main memory (“memory”) 1610, and input/output component(s) 1612, which are in communication via bus 1603. Processor cores 1604 includes cache memory (“cache”) 1606 and controls 1608, which include branch prediction structures and associated search, hit, detect and update logic, which will be described in more detail below. Cache 1606 can include multiple cache levels (not depicted) that are on or off-chip from processor 1604. Memory 1610 can include various data stored therein, e.g., instructions, software, routines, etc., which, e.g., can be transferred to/from cache 1606 by controls 1608 for execution by processor 1604. Input/output component(s) 1612 can include one or more components that facilitate local and/or remote input/output operations to/from computer 1602, such as a display, keyboard, modem, network adapter, etc. (not depicted).

FIG. 17 depicts a block diagram illustrating semiconductor fabrication systems 1700 that supports semiconductor fabrication processes capable of incorporating aspects of the invention. The semiconductor fabrication systems 1700 includes IC design support algorithms 1702, mask design support algorithms 1704, manufacturing support equipment 1706, assembly support equipment 1708, and testing support equipment 1710, configured and arranged as shown. The IC design support algorithms 1702 are configured and arranged to provide computer-aided-design (CAD) assistance with the design of the logic circuits (AND, OR, and NOR gates) that form the various logic components of the IC. Similarly, the mask design support algorithms 1704 are configured and arranged to provide CAD assistance with generating the mask design, which is the representation of an IC in terms of planar geometric shapes that correspond to the patterns of metal, oxide, or semiconductor layers that make up the components of the IC. The mask design places and connects all of the components that make up the IC such that they meet certain criteria, such as performance, size, density, and manufacturability. The manufacturing equipment 1706 is the equipment used in executing the FEOL, MOL, BEOL, and Far-BEOL processes (including singulation processes) used to form the finished wafers and IC chips (or semiconductor die). In general, the wafer manufacturing equipment 1706 comes in various forms, most of which specialize in growing, depositing or removing materials from a wafer. Examples of wafer manufacturing equipment 1706 include oxidation systems, epitaxial reactors, diffusion systems, ion implantation equipment, physical vapor deposition systems, chemical vapor deposition systems, photolithography equipment, etching equipment, polishing equipment and the like. The various types of manufacturing equipment 1702 take turns in depositing and removing (e.g., using the chemicals 1714) different materials on and from the wafer 1712 in specific patterns until a circuit is completely built on the wafer 1712. The assembly equipment 1708 is used to package the IC chips into finished IC packages that are physically ready for use in customer applications. The assembly equipment 1708 can include wafer back-grind systems, wafer saw equipment, die attach machines, wire-bonders, die overcoat systems, molding equipment, hermetic sealing equipment, metal can welders, DTFS (de-flash, trim, form, and singulation) machines, branding equipment, and lead finish equipment. The major components used by the assembly equipment 1708 include but are not limited to lead frames 1716 and substrates 1718. The test equipment 1710 is used to test the IC packages so that only known good devices will be shipped to customers. Test Equipment 1710 can include automatic test equipment (ATE); test handlers; tape and reel equipment; marking equipment; burn-in ovens; retention bake ovens; UV (ultraviolet) erase equipment, and vacuum sealers.

Many of the functional units of the systems described in this specification have been labeled as modules. Embodiments of the invention apply to a wide variety of module implementations. For example, a module can be implemented as a hardware circuit including custom VLSI circuits or gate arrays, off-the-shelf semiconductors such as logic chips, transistors, or other discrete components. A module can also be implemented in programmable hardware devices such as field programmable gate arrays, programmable array logic, programmable logic devices or the like. Modules can also be implemented in software for execution by various types of processors. An identified module of executable code can, for instance, include one or more physical or logical blocks of computer instructions which can, for instance, be organized as an object, procedure, or function. Nevertheless, the executables of an identified module need not be physically located together but can include disparate instructions stored in different locations which, when joined logically together, function as the module and achieve the stated purpose for the module.

Many of the functional units of the systems described in this specification have been labeled as models. Embodiments of the invention apply to a wide variety of model implementations. For example, the models described herein can be implemented as machine learning algorithms and/or natural language processing algorithms configured and arranged to uncover unknown relationships between data/information and generate a model that applies the uncovered relationship to new data/information in order to perform an assigned task of the model. In some aspects of the invention, the models described herein can have all of the features and functionality of the models depicted in FIGS. 14, and 15, which are described in greater detail subsequently herein.

The various components/modules/models of the systems illustrated herein are depicted separately for ease of illustration and explanation. In embodiments of the invention, the functions performed by the various components/modules/models can be distributed differently than shown without departing from the scope of the various embodiments of the invention describe herein unless it is specifically stated otherwise.

For the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and in that manner the conductors, insulators and selectively doped regions are built up to form the final device.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

As used herein, in the context of machine learning algorithms, the terms “input data,” and variations thereof are intended to cover any type of data or other information that is received at and used by the machine learning algorithm to perform training, learning, and/or classification operations.

As used herein, in the context of machine learning algorithms, the terms “training data,” and variations thereof are intended to cover any type of data or other information that is received at and used by the machine learning algorithm to perform training and/or learning operations.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

It will be understood that those skilled in the art, both now and in the future, may make various improvements and enhancements which fall within the scope of the claims which follow.

What is claimed is:

1. A computer-implemented method comprising:
accessing, using a processor system, a process-step sequence comprising a plurality process-steps and a plurality of queue-times; and
applying, using the processor system, a process-step sequence mining operation to the process-step sequence;
wherein the process-step sequence mining operation is operable to make a prediction of an impact of a portion of the process-step sequence on a characteristic of a product generated by the process-step sequence.

2. The computer-implemented method of claim 1, wherein the process-step sequence mining operation comprises:
encoding the process-step sequence to generate an encoded process-step sequence having a plurality of encoded process-steps and a plurality of encoded queue-times; and
applying, using the processor, a dimensionality reduction operation to the encoded process-step sequence.

3. The computer-implemented method of claim 2, wherein:
applying the dimensionality reduction operation to the encoded process-step sequence generates a reduced-dimension encoded process-step sequence; and
the process-step sequence mining operation further comprises applying the reduced-dimension encoded process-step sequence to a predictive model operable to perform a task.

4. The computer-implemented method of claim 3, wherein the task comprises the prediction of the impact of the portion of the process-step sequence on the characteristic of the product generated by the process-step sequence.

5. The computer-implemented method of claim 4, wherein making the prediction of the impact of the portion of the process-step sequence on the characteristic of the product comprises:
performing a first comparison of the reduced-dimension encoded process-step sequence with a first cluster associated with a first measurement range of the characteristic;
performing a second comparison of the reduced-dimension encoded process-step sequence to a second cluster associated with a second measurement range of the characteristic; and
associating the reduced-dimension encoded process-step sequence with the first cluster or the second cluster based on a result of the first comparison and a result of the second comparison.

6. The computer-implemented method of claim 5 further comprising using a pattern sequence extraction module of the processor system to predict a portion of the process-step sequence having a positive impact on the characteristic of the product.

7. The computer-implemented method of claim 4, wherein:
the plurality of process-steps comprises a plurality of semiconductor product fabrication operations;
the product comprises a wafer having dies and completed integrated circuitry ready for testing;
the characteristic is selected from the group consisting of wafer yield, die yield, wafer quality, and die quality;
encoding the process-step sequence to generate the encoded process-step sequence comprise converting the plurality of process-steps and the plurality of queue-times to a plurality of symbols;
the dimensionality reduction operation comprises an embedding operation; and
making the prediction of the impact of the portion of the process-step sequence on the characteristic of the product generated by the process-step sequence comprises evaluating the plurality of symbols against a process-step sequence language domain.

8. A computer system comprising a memory communicatively coupled to a processor system, wherein the processor system is configured to perform processor system operations comprising:
accessing a process-step sequence comprising a plurality process-steps and a plurality of queue-times; and
applying a process-step sequence mining operation to the process-step sequence;
wherein the process-step sequence mining operation is operable to make a prediction of an impact of a portion of the process-step sequence on a characteristic of a product generated by the process-step sequence.

9. The computer system of claim 8, wherein the process-step sequence mining operation comprises:
encoding the process-step sequence to generate an encoded process-step sequence having a plurality of encoded process-steps and a plurality of encoded queue-times; and
applying, using the processor, a dimensionality reduction operation to the encoded process-step sequence.

10. The computer system of claim 9, wherein:
applying the dimensionality reduction operation to the encoded process-step sequence generates a reduced-dimension encoded process-step sequence; and
the process-step sequence mining operation further comprises applying the reduced-dimension encoded process-step sequence to a predictive model operable to perform a task.

11. The computer system of claim 10, wherein the task comprises the prediction of the impact of the portion of the process-step sequence on the characteristic of the product generated by the process-step sequence.

12. The computer system of claim 11, wherein making the prediction of the impact of the portion of the process-step sequence on the characteristic of the product comprises:
performing a first comparison of the reduced-dimension encoded process-step sequence with a first cluster associated with a first measurement range of the characteristic;
performing a second comparison of the reduced-dimension encoded process-step sequence to a second cluster associated with a second measurement range of the characteristic; and
associating the reduced-dimension encoded process-step sequence with the first cluster or the second cluster based on a result of the first comparison and a result of the second comparison.

13. The computer system of claim 12, wherein the processor system operations further comprise using a pattern sequence extraction module of the processor system to predict a portion of the process-step sequence having a positive impact on the characteristic of the product.

14. The computer system of claim 11, wherein:
the plurality of process-steps comprises a plurality of semiconductor product fabrication operations;
the product comprises a wafer having dies and completed integrated circuitry ready for testing;
the characteristic is selected from the group consisting of wafer yield, die yield, wafer quality, and die quality;
encoding the process-step sequence to generate the encoded process-step sequence comprise converting the plurality of process-steps and the plurality of queue-times to a plurality of symbols;
the dimensionality reduction operation comprises an embedding operation; and
making the prediction of the impact of the portion of the process-step sequence on the characteristic of the product generated by the process-step sequence comprises evaluating the plurality of symbols against a process-step sequence language domain.

15. A computer program product analyzing a process-step sequence, the computer program product comprising a computer readable program stored on a computer readable storage medium, wherein the computer readable program, when executed on a processor system, causes the processor system to perform processor system operations comprising:
accessing a process-step sequence comprising a plurality process-steps and a plurality of queue-times; and
applying a process-step sequence mining operation to the process-step sequence;
wherein the process-step sequence mining operation is operable to make a prediction of an impact of a portion of the process-step sequence on a characteristic of a product generated by the process-step sequence.

16. The computer program product of claim 15, wherein the process-step sequence mining operation comprises:
encoding the process-step sequence to generate an encoded process-step sequence having a plurality of encoded process-steps and a plurality of encoded queue-times; and
applying, using the processor, a dimensionality reduction operation to the encoded process-step sequence.

17. The computer program product of claim 16, wherein:
applying the dimensionality reduction operation to the encoded process-step sequence generates a reduced-dimension encoded process-step sequence;
the process-step sequence mining operation further comprises applying the reduced-dimension encoded process-step sequence to a predictive model operable to perform a task; and
the task comprises the prediction of the impact of the portion of the process-step sequence on the characteristic of the product generated by the process-step sequence.

18. The computer program product of claim 17, wherein making the prediction of the impact of the portion of the process-step sequence on the characteristic of the product comprises:
performing a first comparison of the reduced-dimension encoded process-step sequence with a first cluster associated with a first measurement range of the characteristic;
performing a second comparison of the reduced-dimension encoded process-step sequence to a second cluster associated with a second measurement range of the characteristic; and
associating the reduced-dimension encoded process-step sequence with the first cluster or the second cluster based on a result of the first comparison and a result of the second comparison.

19. The computer program product of claim 18, wherein the processor system operations further comprise using a pattern sequence extraction module of the processor system to predict a portion of the process-step sequence having a positive impact on the characteristic of the product.

20. The computer program product of claim 17, wherein:
the plurality of process-steps comprises a plurality of semiconductor product fabrication operations;
the product comprises a wafer having dies and completed integrated circuitry ready for testing;
the characteristic is selected from the group consisting of wafer yield, die yield, wafer quality, and die quality;
encoding the process-step sequence to generate the encoded process-step sequence comprise converting the plurality of process-steps and the plurality of queue-times to a plurality of symbols;
the dimensionality reduction operation comprises an embedding operation; and
making the prediction of the impact of the portion of the process-step sequence on the characteristic of the product generated by the process-step sequence comprises evaluating the plurality of symbols against a process-step sequence language domain.
